(19) United States
(12) Patent Application Publication
(10) Pub. No.: US 2021/0061986 A1
(43) Pub. Date: Mar. 4, 2021

(54) EPOXY RESIN COMPOSITION AND ELECTRONIC COMPONENT DEVICE

(71) Applicant: Hitachi Chemical Company, Ltd., Tokyo (JP)

(72) Inventors: Dongchul KANG, Chiyoda-ku, Tokyo (JP); Masashi YAMAURA, Chiyoda-ku, Tokyo (JP); Kenta ISHIBASHI, Chiyoda-ku, Tokyo (JP); Takuya KODAMA, Chiyoda-ku, Tokyo (JP); Keichi HORI, Chiyoda-ku, Tokyo (JP); Mika TANAKA, Chiyoda-ku, Tokyo (JP)

(21) Appl. No.: 16/981,188

(22) PCT Filed: Mar. 11, 2019
(86) PCT No.: PCT/JP2019/009705

§ 371 Date: Sep. 15, 2020

(30) Foreign Application Priority Data
Mar. 16, 2018 (JP) 2018-049153

(51) Int. Cl. C08L 63/00; C08G 59/62; C08K 3/22; C08K 5/5419; C08K 3/36

(52) U.S. Cl. CPC C08L 63/00; C08G 59/621; C08K 3/22; C08L 2203/206; C08K 3/36; C08K 2003/2227; C08K 5/5419

(57) ABSTRACT

An epoxy resin composition includes an epoxy resin; a curing agent; alumina particles; and a silane compound which does not have a functional group that is reactive with an epoxy group and which has a functional group that is unreactive with an epoxy group, wherein the silane compound has a structure in which the functional group that is unreactive with an epoxy resin is bound to a silicon atom, or is bound to a silicon atom via a chain hydrocarbon group having 1 to 5 carbon atoms.

### TECHNICAL FIELD

The present disclosure relates to an epoxy resin composition and an electronic component device.

### BACKGROUND ART

Conventionally, packages (electronic component devices) in which an element such as a transistor or an integrated circuit (IC) is sealed with a resin such as an epoxy resin are widely used for electronic devices.

In recent years, due to the reductions in size and increasing density of electronic component devices, heat production has been increasing, and consequently, the issue of how to diffuse this heat is receiving considerable attention. In this respect, one approach has been to blend an inorganic filler having high thermal conductivity into a sealing material to increase thermal conductivity.

In a case in which an inorganic filler is mixed with a sealing material, there is a possibility that, as the amount of filler is increased, the viscosity of the sealing material will also increase, whereby flowability is decreased, causing problems such as incomplete filling, wire sweep and the like. In this respect, a method is suggested in which flowability of the sealing material is improved by using a specific phosphorus compound as a curing accelerator (for example, see Patent Literature 1).

### CITATION LIST

### Patent Literature

Patent Literature 1: Japanese Patent Application Laid-Open (JP-A) No. H09-157497

### SUMMARY OF INVENTION

### Technical Problem

However, in conjunction with further advances in the reductions in size and increased density of electronic component devices, there are demands for resin compositions that can be used for sealing materials that are capable of maintaining thermal conductivity at a high level as well as controlling increases in viscosity. Further, it is also required that curability upon molding does not deteriorate even as increases in the viscosity of the resin composition are controlled.

In view of these circumstances, the present disclosure relates to providing an epoxy resin composition that has excellent thermal conductivity, has low viscosity, and has favorable curability upon molding, and an electronic component device having an element sealed with the epoxy resin composition.

### Solution to Problem

A solution to the above problem includes the following embodiments.

<1> An epoxy resin composition, including:

an epoxy resin;

a curing agent;

alumina particles; and

a silane compound which does not have a functional group that is reactive with an epoxy group and which has a functional group that is unreactive with an epoxy group, wherein the silane compound has a structure in which the functional group that is unreactive with an epoxy resin is bound to a silicon atom, or is bound to a silicon atom via a chain hydrocarbon group having 1 to 5 carbon atoms.

<2> The epoxy resin composition according to <1>, wherein a content of the silane compound is from 0.01% by mass to 20% by mass with respect to a total amount of the epoxy resin.
<3> The epoxy resin composition according to <1> or <2>, wherein the functional group that is unreactive with an epoxy resin is at least one selected from the group consisting of a (meth)acryloyl group, a (meth)acryloyloxy group, and a vinyl group.
<4> The epoxy resin composition according to any one of <1> to <3>, wherein the silane compound includes 3-methacryloxypropyltrimethoxysilane.
<5> The epoxy resin composition according to any one of <1> to <4>, wherein a content of the alumina particles is 50% by volume or more.
<6> The epoxy resin composition according to any one of <1> to <5>, further including silica particles.
<7> An electronic component device, having an element sealed with the epoxy resin composition according to any one of <1> to <6>.

### Advantageous Effects of Invention

According to the present disclosure, an epoxy resin composition that has excellent thermal conductivity, has low viscosity, and has favorable curability upon molding, and an electronic component device having an element sealed with the epoxy resin composition are provided.

### DESCRIPTION OF EMBODIMENTS

Embodiments for carrying out the invention will be described in detail below. However, the invention is not limited to the following embodiments. In the following embodiments, components (including elemental steps, etc.) thereof are not essential unless otherwise specified. The same applies to numerical values and ranges, and the numerical values and ranges do not limit the invention.

In the present disclosure, a numerical range described using “to” indicates a range including the numerical values before and after “to” as a minimum value and a maximum value, respectively.

In numerical ranges described herein in a stepwise manner, an upper limit value or a lower limit value described in one numerical range may be replaced with an upper limit value or a lower limit value of another numerical range described in a stepwise manner. In addition, in a numerical range described in the present disclosure, the upper limit value or the lower limit value of the numerical range may be replaced with a value described in the Examples section.

In the present disclosure, a component may include a plurality of different kinds of substances corresponding thereto. In a case in which there are a plurality of different kinds of substances corresponding to a component in a composition, a content or an amount of the component means the total content or amount of the plurality of different kinds of substances present in the composition, unless otherwise specified.

In the present disclosure, particles corresponding to a component may include a plurality of different kinds of particles. In a case in which there are a plurality of different kinds of particles corresponding to a component in a composition, a particle size of the component means a value for a mixture of the plurality of different kinds of particles present in the composition, unless otherwise specified.

In the disclosure, a “(meth)acryloyl group” means at least one of an acryloyl group or an methacryloyl group, and a “(meth)acryloyloxy group” (also referred to as (meth)acryloxy group) means at least one of an acryloyloxy group or a methacryloyloxy group.

<Epoxy Resin Composition>

The epoxy resin composition in the present disclosure includes an epoxy resin; a curing agent; alumina particles; and a silane compound which does not have a functional group that is reactive with an epoxy group and which has a functional group that is unreactive with an epoxy group, wherein the silane compound has a structure in which the functional group that is unreactive with an epoxy resin is bound to a silicon atom, or is bound to a silicon atom via a chain hydrocarbon group having 1 to 5 carbon atoms. In the present disclosure, the “silane compound which does not have a functional group that is reactive with an epoxy group and which has a functional group that is unreactive with an epoxy group, wherein the silane compound has a structure in which the functional group that is unreactive with an epoxy resin is bound to a silicon atom, or is bound to a silicon atom via a chain hydrocarbon group having 1 to 5 carbon atoms” is also referred to as “specific silane compound”. The epoxy resin composition may include other component(s) as necessary.

According to the above configuration, an epoxy resin composition which has excellent thermal conductivity, and in which increases in viscosity are controlled and favorable curability is maintained, can be obtained. The detailed reason why the epoxy resin composition in the present disclosure exhibits the above effect is not necessarily clear; however, it can be presumed as follows.

In general, in a case in which a silane compound is used as a coupling agent in an epoxy resin composition, silane compounds having a functional group that is reactive with an epoxy resin are often used. The main objective here is to improve the dispersibility of an inorganic filler in the epoxy resin, thereby improving the flowability of the composition, by means of chemical bonds between silanol groups of the silane compound and the inorganic filler, as well as chemical bonds between the functional group of the silane compound and the epoxy resin.

On the other hand, since the specific silane compound contained in the epoxy resin composition in the present disclosure has a functional group that is unreactive with an epoxy group and does not have a functional group that is reactive with an epoxy group, the specific silane compound is considered to be present at the surface of the alumina particles without being bonded to the epoxy resin. In general, alumina particles tend to lower the flowability of resin compositions due to the nature of their surface conditions. However, when the specific silane compound is present at the surface of alumina particles, it is presumed that mixability of the alumina particles with the resin is improved, with the specific silane compound functioning as a lubricant. As a result, it is presumed that friction between the alumina particles is reduced, thereby lowering the melt viscosity. Further, it is presumed that, since the viscosity of the epoxy resin composition can be controlled, the amount of alumina particles can be increased, enabling for improved thermal conductivity.

On the other hand, in general, an increase in the amount of components that do not contribute to curing reactions tends to lead to a decline in curability. However, use of the specific silane compound does not lead to significant reductions in the curability of an epoxy resin composition. The reason for the above is not clear; however, it is presumed that, since the specific silane compound has a structure in which a functional group that is unreactive with an epoxy resin is bound to a silicon atom, or is bound to a silicon atom via a chain hydrocarbon group having 1 to 5 carbon atoms, the distance between the silicon atom and the functional group is relatively short, making it less likely that the curing reaction of the epoxy resin composition is hindered.

(Epoxy Resin)

The epoxy resin composition includes an epoxy resin. The type of epoxy resin is not particularly limited as long as it has an epoxy group in a molecule thereof.

Specific examples of the epoxy resin include: a novolac-type epoxy resin (e.g., a phenol novolac-type epoxy resin or an orthocresol novolac-type epoxy resin) obtained by epoxidizing a novolac resin that is obtained by condensing or co-condensing at least one phenolic compound selected from the group consisting of a phenol compound such as phenol, cresol, xylenol, resorcin, catechol, bisphenol A, or bisphenol F, and a naphthol compound such as α-naphthol, β-naphthol, or dihydroxynaphthalene, and an aliphatic aldehyde compound such as formaldehyde, acetaldehyde, or propionaldehyde, under the presence of an acidic catalyst; a triphenylmethane-type epoxy resin obtained by epoxidizing a triphenylmethane-type phenol resin that is obtained by condensing or co-condensing the above-described phenolic compound and an aromatic aldehyde compound such as benzaldehyde or salicylaldehyde under the presence of an acidic catalyst; a copolymerized epoxy resin obtained by epoxidizing a novolac resin that is obtained by co-condensing the above-described phenol compound or naphthol compound with an aldehyde compound under the presence of an acidic catalyst; a diphenylmethane-type epoxy resin that is a diglycidyl ether of bisphenol A, bisphenol F, or the like; a biphenyl-type epoxy resin that is a diglycidyl ether of alkyl-substituted or non-alkyl-substituted biphenol; a stilbene-type epoxy resin which is a diglycidyl ether of a stilbene-type phenol compound; a sulfur atom-containing epoxy resin that is a diglycidyl ether of bisphenol S or the like; an epoxy resin that is a glycidyl ether of an alcohol such as butanediol, polyethylene glycol, or polypropylene glycol; a glycidyl ester-type epoxy resin that is a glycidyl ester of a polycarboxylic acid compound such as phthalic acid, isophthalic acid, or tetrahydrophthalic acid; a glycidyl amine-type epoxy resin obtained by substituting an active hydrogen, bonded to a nitrogen atom of aniline, diaminodiphenylmethane, isocyanuric acid or the like with a glycidyl group; a dicyclopentadiene-type epoxy resin obtained by epoxidizing a co-condensed resin of dicyclopentadiene and a phenol compound; an alicyclic-type epoxy resin obtained by epoxidizing an olefin bond in a molecule, such as vinylcyclohexene diepoxide, 3,4-epoxycyclohexylmethyl-3,4-epoxycyclohexanecarboxylate, or 2-(3,4-epoxy)cyclohexyl-5,5-spiro(3,4-epoxy)cyclohexane-m-dioxane; a para-xylylene-modified epoxy resin that is a glycidyl ether of a para-xylylene-modified phenol resin; a meta xylylene-modified epoxy resin that is a glycidyl ether of a meta-xylylene-modified phenol resin; a terpene-modified epoxy resin that is a glycidyl ether of a terpene-modified phenol resin; a dicyclopentadiene-modified epoxy resin that is a glycidyl ether of a dicyclopentadiene-modified phenol resin; a cyclopentadiene-modified epoxy resin that is a glycidyl ether of a cyclopentadiene-modified phenol resin; a polycyclic aromatic ring-modified epoxy resin that is a glycidyl ether of a polycyclic aromatic ring-modified phenol resin; a naphthalene-type epoxy resin that is a glycidyl ether of a naphthalene ring-containing phenol resin; a halogenated phenol novolac-type epoxy resin; a hydroquinone-type epoxy resin; a trimethylolpropane-type epoxy resin; a linear aliphatic epoxy resin obtained by oxidizing an olefin bond with a peracid such as peracetic acid; and an aralkyl-type epoxy resin obtained by epoxidizing an aralkyl-type phenol resin such as a phenol aralkyl resin or a naphthol aralkyl resin. Further, examples of the epoxy resin also include an epoxidized product of a silicone resin, an epoxidized product of an acrylic resin, and the like. One kind of epoxy resin may be used singly, or two or more kinds thereof may be used in combination.

The epoxy equivalent weight of the epoxy resin (molecular weight/number of epoxy group) is not particularly limited. From the viewpoint of the balance between properties such as moldability, reflow resistance and electric reliability, it is preferable that the epoxy equivalent weight of the epoxy resin is from 100 g/eq to 1000 g/eq, and more preferably from 150 g/eq to 500 g/eq.

The epoxy equivalent weight of an epoxy resin can be measured by a method in accordance with JIS K 7236:2009.

When the epoxy resin is solid, the softening point or melting point of the epoxy resin is not particularly limited, and is preferably from 40° C. to 180° C. from the viewpoints of moldability and reflow resistance, and is more preferably from 50° C. to 130° C. from the viewpoint of handleability in preparing an epoxy resin composition.

The melting point of an epoxy resin is a value measured by DSC (differential scanning calorimetry), and the softening point of an epoxy resin is a value measured by a method in accordance with JIS K 7234:1986 (the ring-and-ball method).

The content of the epoxy resin in the epoxy resin composition is preferably from 0.5% by mass to 50% by mass, more preferably from 2% by mass to 30% by mass, and still more preferably from 2% by mass to 20% by mass, from the viewpoints of strength, flowability, heat resistance, moldability and the like.

(Curing Agent)

The epoxy resin composition includes a curing agent. The type of curing agent is not particularly limited, and may be selected depending on the properties desired for the epoxy resin composition or the like.

Examples of the curing agent include a phenol curing agent, an amine curing agent, an acid anhydride curing agent, a polymercaptan curing agent, a polyaminoamide curing agent, an isocyanate curing agent, and a blocked isocyanate curing agent. From the viewpoint of improving heat resistance, the curing agent is preferably one that has a phenolic hydroxyl group in a molecule thereof (i.e., a phenol curing agent).

Specific examples of the phenol curing agent include: a polyphenol compound such as resorcin, catechol, bisphenol A, bisphenol F, or substituted or unsubstituted biphenol; a novolac-type phenol resin obtained by condensing or co-condensing at least one phenolic compound selected from the group consisting of a phenol compound such as phenol, cresol, xylenol, resorcin, catechol, bisphenol A, bisphenol F, phenylphenol, or aminophenol, and a naphthol compound such as α-naphthol, β-naphthol, or dihydroxynaphthalene, with an aldehyde compound such as formaldehyde, acetaldehyde, propionaldehyde, benzaldehyde or salicylaldehyde, under the presence of an acidic catalyst; an aralkyl-type phenol resin, such as a phenol aralkyl resin or a naphthol aralkyl resin, synthesized from the above-described phenolic compound and dimethoxyparaxylene, bis(methoxymethyl)biphenyl or the like; a para-xylylene and/or meta-xylylene-modified phenol resin; a melamine-modified phenol resin; a terpene-modified phenol resin; a dicyclopentadiene-type phenol resin and a dicyclopentadiene-type naphthol resin synthesized by copolymerization of the above-described phenolic compound and dicyclopentadiene; a cyclopentadiene-modified phenol resin; a polycyclic aromatic ring-modified phenol resin; a biphenyl-type phenol resin; a triphenylmethane-type phenol resin obtained by condensing or co-condensing the above-described phenolic compound and an aromatic aldehyde compound such as benzaldehyde or salicylaldehyde under the presence of an acidic catalyst; and a phenol resin obtained by copolymerizing two or more kinds thereof. One kind of phenol curing agent may be used singly, or two or more kinds thereof may be used in combination.

In particular, a biphenyl-type phenol resin is preferable from the viewpoint of flame retardancy; an aralkyl-type phenol resin is preferable from the viewpoints of reflow resistance and curability; a dicyclopentadiene-type phenol resin is preferable from the viewpoint of low moisture absorbency; a triphenylmethane-type phenol resin is preferable from the viewpoints of heat resistance, low coefficient of thermal expansion and low warpage; and a novolac-type phenol resin is preferable from the viewpoint of curability. It is preferable that the epoxy resin composition includes at least one of the above phenol resins.

The functional group equivalent weight of the curing agent (or the hydroxyl group equivalent weight in the case of a phenol curing agent) is not particularly limited, and is preferably from 70 g/eq to 1000 g/eq, and more preferably from 80 g/eq to 500 g/eq, from the viewpoint of the balance between various properties such as moldability, reflow resistance, and electric reliability.

The functional group equivalent weight of a curing agent (or a hydroxyl group equivalent weight in the case of a phenol curing agent) is a value measured by a method in accordance with JIS K 0070:1992.

When the curing agent is solid, the softening point or melting point of the curing agent is not particularly limited. The softening point or melting point of the curing agent is preferably from 40° C. to 180° C. from the viewpoints of moldability and reflow resistance, and more preferably from 50° C. to 130° C. from the viewpoint of handleability upon preparation of the epoxy resin composition.

The melting point or softening point of a curing agent is a value that is measured in the same manner as the melting point or softening point of the epoxy resin.

The ratio between the number of equivalent of the epoxy resin and the number of equivalent of the curing agent, i.e., the ratio of the number of functional groups in the curing agent to the number of epoxy groups in the epoxy resin (number of functional groups in the curing agent/number of epoxy groups in the epoxy resin) is not particularly limited. From the viewpoint of reducing respective unreacted components, the ratio between the number of equivalent of the epoxy resin and the number of equivalent of the curing agent is preferably from 0.5 to 2.0, and more preferably from 0.6 to 1.3. From the viewpoints of moldability and reflow resistance, the ratio between the number of equivalent of the epoxy resin and the number of equivalent of the curing agent is still more preferably from 0.8 to 1.2.

(Alumina Particles)

The epoxy resin composition includes alumina particles as an inorganic filler. The epoxy resin composition may further include an inorganic filler other than the alumina particles.

The content of the alumina particles in the epoxy resin composition is not particularly limited. From the viewpoint of the thermal conductivity of a curing product, the content of the alumina particles is preferably 30% by volume or higher, more preferably 35% by volume or higher, still more preferably 40% by volume or higher, particularly preferably 45% by volume or higher, and extremely preferably from 50% by volume or higher, with respect to the total amount of the epoxy resin composition. The upper limit of the content of the alumina particles is not particularly limited, and from the viewpoints of improving flowability, reducing viscosity and the like, the content is preferably less than 100% by volume, more preferably 99% by volume or lower, and still more preferably 98% by volume or lower. The content of the alumina particles in the epoxy resin composition is preferably from 30% by volume to less than 100% by volume, more preferably from 35% by volume to 99% by volume, still more preferably from 40% by volume to 98% by volume, particularly preferably from 45% by volume to 98% by volume, and extremely preferably from 50% by volume to 98% by volume. The content of alumina particles in an epoxy resin composition can be measured by, for example, the method of measuring the content of an inorganic filler described later.

The volume average particle diameter of the alumina particles is not particularly limited. The volume average particle diameter of the alumina particles is preferably 0.1 μm or more, and more preferably 0.3 μm or more. Further, the volume average particle diameter of the alumina particles is preferably 80 μm or less, and more preferably 50 μm or less. When the volume average particle diameter of the alumina particles is 0.1 μm or more, increases in the viscosity of the epoxy resin composition tend to be controlled. When the volume average particle diameter of the alumina particles is 80 μm or less, there is a tendency for the mixability of the alumina particles in the epoxy resin composition to be improved, and for uneven localization of the alumina particles to be controlled, whereby unevenness of the thermal conductivity of a cured product can be controlled. Further, there is a tendency for the fillability of the alumina particles to be improved even when the epoxy resin composition is used for sealing narrow areas. The volume average particle diameter of the alumina particles can be measured as a particle diameter at which the cumulative volume reaches 50%, counting from particles having a smaller particle diameter, in a volume-based particle size distribution (D50) measured using a laser scattering-diffraction particle size distribution analyzer.

The shape of the alumina particles is not limited, and examples thereof include a spherical shape and a polyhedron. From the viewpoint of flowability, the particle shape of the alumina particles is preferably spherical, and it is preferable that the particle size distribution of the alumina particles is broadly distributed. For example, when the alumina particles are contained at a content of 75% by volume or more with respect to the epoxy resin composition, it is preferable that 70% by volume or more of the entire alumina particles are in a spherical shape, and that the particle size of the spherical particles broadly ranges from 0.1 μm to 80 μm. Such alumina particles tend to form a densely-filled structure, and therefore, increases in the viscosity of the material can be controlled even if the content of alumina particles is increased, whereby an epoxy resin composition having an excellent flowability can be obtained.

The epoxy resin composition may include an inorganic filler other than alumina particles. Such an inorganic filler other than alumina particles is not particularly limited, and examples thereof include an inorganic material such as particles of fused silica, crystalline silica, glass, calcium carbonate, zirconium silicate, calcium silicate, silicon nitride, aluminum nitride, boron nitride, magnesium oxide, silicon carbide beryllia, zirconia, zircon, forsterite, steatite, spinel, mullite, titania, talc, clay, or mica. An inorganic filler having a flame-retardant property may also be used. Examples of the inorganic filler having a flame-retardant property include a complex metal hydroxide such as aluminum hydroxide, magnesium hydroxide, or magnesium-zinc complex hydroxide, and zinc borate. One kind of inorganic filler may be used singly, or two or more kinds thereof may be used in combination. In particular, from the viewpoint of the balance between properties such as thermal conductivity and the coefficient of thermal expansion of the cured product, combined use of alumina particles and silica particles are preferable. Further, from the viewpoint of thermal conductivity, combined use of magnesium oxide is also preferable.

One kind of inorganic filler other than alumina particles may be used singly, and two or more kinds thereof may be used in combination. Here, “two or more kinds of inorganic filler are used in combination” encompasses, for example, a case in which two or more kinds of inorganic filler of the same material having different volume average particle sizes are used, a case in which two or more kinds of inorganic filler of different materials having the same volume average particle size are used, and a case in which two or more kinds of inorganic filler of different materials having different volume average particle sizes are used.

The content of the inorganic filler with respect to the entire mass of the epoxy resin composition is not particularly limited. From the viewpoint of the thermal conductivity of a cured product, the content of the inorganic filler is preferably 30% by volume or more, more preferably 35% by volume or more, still more preferably 40% by volume or more, particularly preferably 45% by volume or more, and extremely preferably 50% by volume or more, with respect to the entire amount of the epoxy resin composition. The upper limit of the content of the inorganic filler is not particularly limited, and from the viewpoints of improving flowability, lowering viscosity and the like, the content of the inorganic filler is preferably less than 100% by volume, more preferably 99% by volume or less, and still more preferably 98% by volume or less. The content of the inorganic filler is preferably from 30% by volume to less than 100% by volume, more preferably from 35% by volume to 99% by volume, still more preferably from 40% by volume to 98% by volume, particularly preferably 45% by volume to 98% by volume, and extremely preferably from 50% by volume to 98% by volume.

The content of the inorganic filler with respect to the entire mass of the epoxy resin composition is measured as follows. First, the mass of the cured product of the epoxy resin composition (also referred to as “epoxy resin molded body”) is measured, and then the epoxy resin molded product is fired at 400° C. for two hours, followed by firing at 700° C. for three hours, thereby evaporating the resin components, and the mass of the remaining inorganic filler is measured. Based on the thus-obtained mass and the specific gravity, the volume, and thereby the ratio of the volume of the inorganic filler to the entire volume of the cured product of the epoxy resin composition (epoxy resin molded body), are calculated, to obtain the content of the inorganic filler.

From the viewpoint of improving fillability into narrow spaces in a case in which the epoxy resin composition is used as a mold underfill material and or like, the maximum particle diameter (also referred to as “cut point”) of the inorganic filler may be controlled. The maximum particle diameter of the inorganic filler may be adjusted as appropriate, and from the viewpoint of fillability, the maximum particle diameter of the inorganic filler is preferably 105 μm or less, more preferably 75 μm or less, and may be 60 μm or less, and may be 40 μm or less. The maximum particle diameter can be measured using a laser scattering-diffraction particle size distribution analyzer (HORIBA, Ltd, product name: LA920).

When the epoxy resin composition includes alumina particles and an inorganic filler other than alumina particles as an inorganic filler, the content of the alumina particles with respect to the entire amount of the inorganic filler is preferably from 30% by mass or more, more preferably from 35% by mass or more, and still more preferably from 40% by mass or more. The upper limit of the content of the alumina particles with respect to the entire amount of the inorganic filler is not particularly limited, and may be 100% by mass or less, 90% by mass or less, or 85% by mass or less.

(Specific Silane Compound)

The epoxy resin composition includes a specific silane compound. The specific silane compound does not have a functional group that is reactive with an epoxy group and has a functional group that is unreactive with an epoxy group, and has a structure in which the functional group that is unreactive with an epoxy resin is bound to a silicon atom, or is bound to a silicon atom via a chain hydrocarbon group having 1 to 5 carbon atoms. Hereinafter, the functional group that is unreactive with an epoxy group in a specific silane compound is also referred to as “specific functional group”.

The term “a functional group that is unreactive with an epoxy group” refers to a functional group which does not chemically react with an epoxy group or whose reaction with an epoxy group is extremely slow such that changes in the properties of the epoxy resin composition caused by such a reaction are practically negligible. The term “a functional group that is reactive with an epoxy group” refers to a functional group other than the “functional group that is unreactive with an epoxy group”. A “functional group” of a silane compound refers to an atom or a group of atoms contained in the molecule of the silane compound, from which atom or group of atoms the reactivity of the silane compound derives. Whether or not a functional group of a silane compound is unreactive can be determined using, for example, a differential scanning calorimetry (DSC).

The structure in which “the functional group that is unreactive with an epoxy resin is bound to a silicon atom”, in the “structure in which the functional group that is unreactive with an epoxy resin is bound to a silicon atom, or is bound to a silicon atom via a chain hydrocarbon group having 1 to 5 carbon atoms”, refers to a structure in which the specific functional group is directly bound to the silicon atom.

Examples of the specific functional group include a (meth)acryloyl group, a (meth)acryloyloxy group, a vinyl group, and a styryl group.

On the other hand, examples of the “functional group that is reactive with an epoxy resin” includes a group having an amine structure such as an amino group or a phenylamino group, an epoxy group, a thiol group, an isocyanate group, an isocyanurate group, and an ureido group.

The specific functional group is preferably at least one selected from the group consisting of a (meth)acryloyl group, a (meth)acryloyloxy group, and a vinyl group, and is more preferably a (meth)acryloyloxy group.

The specific silane compound may have one specific functional group in a molecule thereof, or may have multiple of specific functional groups in a molecule thereof. The number of the specific functional group(s) in a molecule of the specific silane compound is preferably from 1 to 4, more preferably from 1 to 3, and still more preferably 1.

In the specific silane compound, the specific functional group is either bound to a silicon atom or bound to a silicon atom via a chain hydrocarbon group having 1 to 5 carbon atoms. When the specific functional group is bound to a silicon atom via a chain hydrocarbon group having 1 to 5 carbon atoms, the number of carbon atom(s) of the chain hydrocarbon group is preferably from 2 to 4, and more preferably 3, from the viewpoints of moldability and lowering viscosity. In the present disclosure, the number of carbon atom(s) of a chain hydrocarbon group refers to the number of carbon atom(s) excluding those in a branch or a substituent.

When the specific functional group is bound to a silicon atom via a chain hydrocarbon group having 1 to 5 carbon atoms, the specific functional group may be present at the end of the chain hydrocarbon group, or may be present at a side chain of the chain hydrocarbon group. From the viewpoint of controlling the viscosity, the specific functional group is preferably present at the end of the chain hydrocarbon group.

The chain hydrocarbon group may have a branched chain. When the chain hydrocarbon group has a branched chain, the number of carbon atom(s) in the branched chain is preferably 1 or 2. The chain hydrocarbon group preferably does not have a branched chain.

The chain hydrocarbon group may have a substituent other than the specific functional group. When the chain hydrocarbon group has a substituent, the substituent is not particularly limited, and examples thereof include an alkoxy group, an aryl group, and an aryloxy group. The chain hydrocarbon group preferably does not have a substituent other than the specific functional group.

The chain hydrocarbon group may or may not have an unsaturated bond, and preferably does not have an unsaturated bond.

Hereinafter, the specific functional group directly bound to a silicon atom, or a group containing a chain hydrocarbon group having 1 to 5 carbon atoms bound to a silicon atom and a specific functional group, is referred to as “a group containing a specific functional group”.

The number of the group(s) containing a specific functional group in the specific silane compound may be 1 to 4, and is preferably 1 to 3, more preferably 1 or 2, and still more preferably 1. When the number of the group(s) containing a specific functional group is 1 to 3, the other group(s) bound to the silicon atom is not particularly limited, and may be each independently a hydrogen atom, an alkyl group having 1 to 5 carbon atoms, an alkoxy group having 1 to 5 carbon atoms, an aryl group, an aryloxy group or the like, and is preferably an alkyl group having 1 to 5 carbon atoms or an alkoxy group having 1 to 5 carbon atoms, and more preferably a methyl group, an ethyl group, a methoxy group, or an ethoxy group. In particular, it is preferable that one group containing a specific functional group is bound to a silicon atom, and that, to the other three bonding sites of the silicon atom, an alkyl group having 1 to 5 carbon atoms or an alkoxy group having 1 to 5 carbon atoms is each independently bound. It is more preferable that one group containing a specific functional group is bound to a silicon atom, and that, to the other three bonding sites of the silicon atom, a methyl group, an ethyl group, a methoxy group or an ethoxy group is each independently bound.

Examples of the specific silane compound include 3-(meth)acryloxypropylmethyldimethoxysilane, 3-(meth)acryloxypropyltrimethoxysilane, 3-(meth)acryloxypropylmethyldiethoxysilane, 3-(meth)acryloxypropyltriethoxysilane, vinyltrimethoxysilane, vinyltriethoxysilane, and p-styryltrimethoxysilane. In particular, 3-(meth)acryloxypropyltrimethoxysilane is preferable from the viewpoints of controlling viscosity, and curability of the epoxy resin composition. One kind of specific silane compound may be used singly, or two or more kinds thereof may be used in combination.

The specific silane compound may be one that is synthesized, or may be one that is commercially available. Examples of a silane compound that is commercially available include KBM-502 (3-methacryloxypropylmethyldimethoxysilane), KBM-503 (3-methacryloxypropyltrimethoxysilane), KBE-502 (3-methacryloxypropylmethyl diethoxysilane), KBE-503 (3-methacryloxypropyltriethoxysilane), and KBM-5103 (3-acryloxypropyltrimethoxysilane), manufactured by Shin-Etsu Chemical Co., Ltd.

The content of the specific silane compound in the epoxy resin composition is not particularly limited. The content of the specific silane compound is preferably 0.01% by mass to 20% by mass with respect to the total amount of the epoxy resin. For example, from the viewpoint of the balance between viscosity and curability of the composition, the content of the specific silane compound may be from 0.01% by mass to 10% by mass with respect to the total amount of the epoxy resin. From the viewpoint of further controlling the increase in the viscosity, the content of the specific silane compound may be from 10% by mass to 20% by mass, or from 15% by mass to 20% by mass, with respect to the total amount of the epoxy resin.

The epoxy resin composition may include a silane compound other than the specific silane compound. The silane compound other than the specific silane compound is not particularly limited as long as it is generally used for epoxy resin compositions, and may be a silane compound that is reactive with an epoxy group, or may be a silane compound that is unreactive with an epoxy group. Examples of the silane compound other than the specific silane compound include an epoxysilane, a mercaptosilane, an aminosilane, an alkylsilane, an ureidosilane, a (meth)acrylsilane (not including the specific silane compound), and a vinylsilane (not including the specific silane compound). One kind of silane compound other than the specific silane compound may be used singly, or two or more kinds thereof may be used in combination.

From the viewpoint of favorably exhibiting the function of the specific silane compound, the content of the silane compound other than the specific silane compound with respect to the total amount of the specific silane compound and the silane compound other than the specific silane compound is preferably 30% by mass or less, more preferably 20% by mass or less, and still more preferably 10% by mass or less.

The epoxy resin composition may include a coupling agent other than a silane compound. Examples of the coupling agent other than a silane compound include known coupling agents such as a titanium compound, an aluminum chelate compound, an aluminum/zirconium compound or the like. One kind of coupling agent other than a silane compound may be used singly, or two or more kinds thereof may be used in combination.

(Curing Accelerator)

The epoxy resin composition may include a curing accelerator. The type of curing accelerator is not particularly limited, and may be selected depending on the type of epoxy resin, desired properties of the epoxy resin, or the like.

Examples of the curing accelerator include: a cycloamidine compound, such as 2-methylimidazole, 2-phenylimidazole, 2-phenyl-4-methylimidazole, 2-heptadecylimidazole, or a diazabycycloalkene such as 1,5-diazabicyclo[4.3.0]non-5-ene (DBN) or 1,8-diazabicyclo[5.4.0]undec-7-ene (DBU); a derivative of the cycloamidine compound; a phenol novolac salt of the cycloamidine compound or the derivative thereof; a compound that is intramolecularly polarized, which is obtained by adding a compound having a π bond, such as maleic anhydride, diazophenylmethane, or a quinone compound such as 1,4-benzoquinone, 2,5-toluquinone, 1,4-naphthoquinone, 2,3-dimethylbenzoquinone, 2,6-dimethylbenzoquinone, 2,3-dimethoxy-5-methyl-1,4-benzoquinone, 2,3-dimethoxy-1,4-benzoquinone, or phenyl-1,4-benzoquinone, to the foregoing compounds; a cycloamidinium compound such as a tetraphenyl borate salt of DBU, a tetraphenyl borate salt of DBN, a tetraphenyl borate salt of 2-ethyl-4-methylimidazole or a tetraphenyl borate salt of N-methylmorpholine; a tertiary amine compound such as pyridine, triethylamine, triethylenediamine, benzyldimethylamine, triethanolamine, dimethylaminoethanol, or tris(dimethylaminomethyl)phenol; a derivative of the tertiary amine compound; an ammonium salt compound such as tetra-n-butylammonium acetate, tetra-n-butylammonium phosphate, tetraethylammonium acetate, tetra-n-hexylammonium benzoate, or tetrapropylammonium hydroxide; a tertiary phosphine such as triphenylphosphine, diphenyl(p-tolyl)phosphine, a tris(alkylphenyl)phosphine, a tris(alcoxyphenyl)phosphine, a tris(alkylalcoxyphenyl)phosphine, a tris(dialkylphenyl)phosphine, a tris(trialkylphenyl)phosphine, a tris(tetraalkylphenyl)phosphine, a tris(dialcoxyphenyl)phosphine, a tris(trialcoxyphenyl)phosphine, a tris(tetraalcoxyphenyl)phosphine, a tri alkylphosphine, a di alkylarylphosphine, or an alkyldiarylphosphine; a phosphine compound such as a complex of the tertiary phosphine described above and an organic boron compound; a compound that is intramolecularly polarized, which is obtained by adding a compound having a π bond such as maleic anhydride, diazophenylmethane, or a quinone compound such as 1,4-benzoquinone, 2,5-toluquinone, 1,4-naphtoquinone, 2,3-dimethylbenzoquinone, 2,6-dimethylbenzoquinone, 2,3-dimethoxy-5-methyl-1,4-benzoquinone, 2,3-dimethoxy-1,4-benzoquinone, or phenyl-1,4-benzoquinone, to the tertiary phosphine or the phosphine compound described above; a compound that is intramolecularly polarized, which is obtained by reacting the tertiary phosphine or the phosphine compound described above and a halogenated phenol compound such as 4-bromophenol, 3-bromophenol, 2-bromophenol, 4-chlorophenol, 3-chlorophenol, 2-chlorophenol, 4-iodophenol, 3-iodophenol, 2-iodophenol, 4-bromo-2-methylphenol, 4-bromo-3-methylphenol, 4-bromo-2,6-dimethylphenol, 4-bromo-3,5-dimethylphenol, 4-bromo-2,6-di-t-buthylphenol, 4-chloro-1-naphthol, 1-bromo-2-naphthol, 6-bromo-2-naphthol, or 4-bromo-4′-hydroxybiphenyl, followed by dehydrohalogenation; a tetra-substituted phosphonium such as tetraphenylphosphonium, a tetra-substituted phosphonium having no phenyl group bonded to a boron atom such as tetra-p-tolylborate, or a tetra-substituted borate; and a salt of tetraphenylphosphonium and a phenol compound. One kind of curing accelerator may be used singly, or two or more kinds thereof may be used in combination.

When the epoxy resin composition includes a curing accelerator, the amount of the curing accelerator is preferably from 0.1 parts by mass to 30 parts by mass, and more preferably from 1 part by mass to 15 parts by mass, with respect to 100 parts by mass of the resin component (i.e., the sum of the resin and the curing agent). When the amount of the curing accelerator is 0.1 parts by mass with respect to 100 parts by mass of the resin component, there is a tendency for the resin composition to be favorably cured in a short time. When the amount of the curing accelerator is 30 parts by mass or lower with respect to 100 parts by mass of the resin component, there is a tendency for favorable molded product to be obtained, without an excessively high curing speed.

[Additives]

The epoxy resin composition may include, in addition to the above-described components, additive(s) such as an ion exchanger, a mold release agent, a flame retardant, a colorant, a stress relaxation agent or the like, examples of which are listed below. The epoxy resin composition may also include additive(s) known in the art as necessary, besides the additives listed below.

(Ion Exchanger)

The epoxy resin composition may include an ion exchanger. In particular, in a case in which the epoxy resin composition is used as a molding material for sealing, the epoxy resin composition preferably includes an ion exchanger from the viewpoint of improving moisture resistance and high temperature endurance of an electronic component device provided with an element to be sealed. The ion exchanger is not particularly limited, and a conventionally known ion exchanger can be used. Specifically, examples include a hydrotalcite compound and a hydrous oxide of at least one element selected from the group consisting of magnesium, aluminum, titanium, zirconium, and bismuth. One kind of ion exchanger may be used singly, or two or more kinds thereof may be used in combination. Of these, a hydrotalcite represented by the following Formula (A) is preferable.

Mg_{(1-X)}Al_{X}(OH)₂(CO₃)_{X/2}.mH₂O (A)

(0<X≤0.5; m is a positive number.)

When the epoxy resin composition includes an ion exchanger, the amount of the ion exchanger is not particularly limited as long as it is sufficient for capturing ions such as halogen ions. For example, the amount of the ion exchanger with respect to 100 parts by mass of the resin component is preferably from 0.1 parts by mass to 30 parts by mass, more preferably from 1 part by mass to 10 parts by mass.

(Mold Release Agent)

The epoxy resin composition may include a mold release agent from the viewpoint of obtaining favorable releasing property with a mold upon molding. The mold release agent is not particularly limited, and a conventionally known mold release agent may be used. Specific examples include: carnauba wax; a higher fatty acid such as montanic acid or stearic acid; a higher fatty acid metal salt; an ester-based wax such as montanic acid ester; and a polyolefin-based wax such as oxidized polyethylene or non-oxidized polyethylene. One kind of mold release agent may be used singly, or two or more kinds thereof may be used in combination.

When the epoxy resin composition includes a mold release agent, the amount of the mold release agent is preferably from 0.01 parts by mass to 10 parts by mass, and more preferably from 0.1 parts by mass to 5 parts by mass, with respect to 100 parts by mass of the resin component. When the amount of the mold release agent with respect to 100 parts by mass of the resin component is 0.01 parts by mass or more, sufficient mold releasing property tends to be achieved. When the amount of the mold release agent is 10 parts by mass or less, more favorable adhesiveness and curability tend to be achieved.

(Flame Retardant)

The epoxy resin composition may include a flame retardant. The flame retardant is not particularly limited, and a conventionally known flame retardant may be used. Specific examples include an organic or inorganic compound having a halogen atom, an antimony atom, a nitrogen atom or a phosphorus atom, and a metal hydroxide. One kind of flame retardant may be used singly, or two or more kinds thereof may be used in combination.

When the epoxy resin composition includes a flame retardant, the amount of the flame retardant is not particularly limited as long as a desired flame retardant effect can be obtained. For example, the amount of the flame retardant is preferably from 1 part by mass to 30 parts by mass, and more preferably from 2 parts by mass to 20 parts by mass, with respect to 100 parts by mass of the resin component.

(Colorant)

The epoxy resin composition may further include a colorant. Examples of the colorant include known colorants such as carbon black, an organic dye, an organic pigment, titanium oxide, red lead, or colcothar. The amount of the colorant may be selected as necessary, depending on the purpose or the like. One kind of colorant may be used singly, or two or more kinds thereof may be used in combination.

(Stress Relaxation Agent)

The epoxy resin composition may include a stress relaxation agent such as silicone oil or silicone rubber particles. By using a stress relaxation agent, the warpage deformation of a package and the occurrence of package cracking can be further reduced. Examples of the stress relaxation agent include generally used known stress relaxation agents (also referred to as “flexible agents”). Specific examples thereof include a thermoplastic elastomer such as a silicone-based thermoplastic elastomer, a styrene-based thermoplastic elastomer, an olefin-based thermoplastic elastomer, an urethane-based thermoplastic elastomer, a polyester-based thermoplastic elastomer, a polyether-based thermoplastic elastomer, a polyamide-based thermoplastic elastomer, and a polybutadiene-based thermoplastic elastomer; rubber particles of, for example, natural rubber (NR), acrylonitrile-butadiene rubber (NBR), acrylic rubber, urethane rubber, or silicone powder; and rubber particles having a core-shell structure of, for example, a methyl methacrylate-styrene-butadiene copolymer (MBS), a methyl methacrylate-silicone copolymer, or a methyl methacrylate-butyl acrylate copolymer. One kind of stress relaxation agent may be used singly, or two or more kinds thereof may be used in combination.

[Physical Properties of Epoxy Resin Composition]

(Viscosity of Epoxy Resin Composition)

The viscosity of the epoxy resin composition is not particularly limited. It is preferable that the viscosity is adjusted such that a desired viscosity is obtained depending on the molding method, the composition of the epoxy resin composition, or the like.

For example, when an epoxy resin composition is molded by compression molding, the viscosity of the epoxy resin composition at 175° C. is preferably 200 Pa·s or lower, more preferably 150 Pa·s or lower, and still more preferably 100 Pa·s or lower, from the viewpoint of lowering the possibility of wire sweep. The lower limit of the viscosity is not particularly limited, and the viscosity may be, for example, 10 Pa·s or higher.

Further, for example, when an epoxy resin composition is molded by transfer molding, the viscosity of the epoxy resin composition at 175° C. is preferably 200 Pa·s or lower, more preferably 150 Pas or lower, and still more preferably 100 Pa·s or lower, from the viewpoint of lowering the possibility of wire sweep. The lower limit of the viscosity is not particularly limited, and the viscosity may be, for example, 10 Pa·s or higher.

The viscosity of an epoxy resin composition can be measured using, for example, a Koka-type flow tester (for example, manufactured by Shimadzu Corporation).

Further, the viscosity of the epoxy resin composition may also be determined using a spiral flow test. For example, the viscosity can be evaluated by a flow distance measured as a length of molded body obtained by injecting an epoxy resin composition into a spiral flow mold that is compliant with the standard (EMMI-1-66) at an oil pressure of 70 kgf/cm² (approximately 6.86 MPa) in the pressure at the bottom of the plunger, and molded under the condition of 175° C. for 120 seconds. The flow distance measured by the above condition is preferably 67 inches (170 cm) or more, more preferably 70 inches (178 cm) or more, still more preferably 75 inches (191 cm) or more, particularly preferably 80 inches (203 cm) or more, and extremely preferably 85 inches (216 cm) or more. Here, the values in parentheses (cm) are converted values.

(Thermal Conductivity of Cured Product)

The thermal conductivity of a cured product of the epoxy resin composition is not particularly limited. From the viewpoint of obtaining desired heat dissipation, the thermal conductivity at room temperature (25° C.) may be 3.0 W/(m·K) or higher, 4.0 W/(m·K) or higher, 5.0 W/(m·K) or higher, 6.0 W/(m·K) or higher, 7.0 W/(m·K) or higher, or 8.0 W/(m·K) or higher. The upper limit of the thermal conductivity is not particularly limited, and the thermal conductivity may be 9.0 W/(m·K) or lower. The thermal conductivity of a cured product can be measured by the xenon-flush (Xe-flash) method (for example, LFA467, HyperFlash Apparatus (product name), manufactured by NETZSCH).

(High Temperature Hardness of Cured Product)

The high temperature hardness of a cured product of the epoxy resin composition is not particularly limited. For example, the high temperature hardness of a cured product, measured using a Shore D Hardness tester, the epoxy resin composition being molded under the conditions of 175° C., 120 seconds and a pressure of 7 MPa, is preferably 60 or more, more preferably 65 or more, and still more preferably 70 or more.

[Method of Preparing Epoxy Resin Composition]

A method of preparing the epoxy resin composition is not particularly limited. Examples of general methods include thoroughly mixing respective components using a mixer or the like, followed by melt kneading the composition using a mixing roll, an extruder or the like, and cooling and pulverizing the composition. More specifically, examples include a method in which the components described above are mixed and stirred, melt kneaded using a kneader, a roll, an extruder or the like that have been preliminarily heated at 70° C. to 140° C., cooled, and pulverized.

The epoxy resin composition may be solid or may be liquid at an ordinary temperature and pressure (for example, at 25° C. under atmospheric pressure), and is preferably solid. The form of the epoxy resin composition in a case in which the epoxy resin composition is solid is not particularly limited, and the composition may be in the form of a powder, particles, tablets or the like. The size and the mass of the epoxy resin composition in a case in which the epoxy resin composition is in the form of a tablet is preferably adjusted in accordance with the molding conditions of the package from the viewpoint of handleability.

<Electronic Component Device>

The electronic component device in an embodiment of the present disclosure has an element sealed with the epoxy resin composition described above.

Examples of the electronic component device include an electronic component device in which an element part, obtained by mounting an element (e.g., an active element such as a semiconductor chip, a transistor, a diode, or a thyristor, or a passive element such as a capacitor, a resistor, or a coil) on a support member such as a lead frame, a pre-wired tape carrier, a wiring board, a glass, a silicon wafer, or an organic substrate, is sealed with the epoxy resin composition.

More specific examples include: a general resin-sealed type IC, such as a DIP (Dual Inline Package), a PLCC (Plastic Leaded Chip Carrier), a QFP (Quad Flat Package), an SOP (Small Outline Package), an SOJ (Small Outline J-lead package), a TSOP (Thin Small Outline Package), or a TQFP (Thin Quad Flat Package), having a structure formed by fixing an element on a lead frame, connecting the terminal part of the element, such as a bonding pad, to the lead part by wire bonding, bumping or the like, and performing a sealing process by transfer molding or the like using the epoxy resin composition; a TCP (Tape Carrier Package) having a structure formed by sealing, with the epoxy resin composition, an element connected to a tape carrier with bumps; a COB (Chip On Board) module, a hybrid IC, a multi-chip module, and the like, having a structure formed by sealing, with the epoxy resin composition, an element connected to the wiring formed on a support member by wire bonding, flip-chip bonding, soldering, or the like; and a BGA (Ball Grid Array), a CSP (Chip Size Package), an MCP (Multi Chip Package), and the like, having a structure formed by mounting an element on a surface of a support member, at the rear surface of which terminals for connecting to the wiring board have been formed, connecting the element and the wiring formed on the support member by bumping or wire bonding, and then sealing the element with the epoxy resin composition. Further, the epoxy resin composition may be suitably used for a printed wiring board.

Examples of the method of sealing an electronic component device with the epoxy resin composition include low pressure transfer molding, injection molding, compression molding and the like.

### Examples

Hereinafter, the embodiments described above will be further specifically illustrated in reference to the Examples. However, the scope of the embodiments is not limited to these Examples.

<Preparation of Epoxy Resin Composition>

First, respective components listed below are prepared.

[Epoxy Resin]
Epoxy Resin A: A bisphenol F-type epoxy resin having an epoxy equivalent weight of 187 g/eq to 197 g/eq, and a melting point of 61° C. to 71° C. (YSLV-80XY (product name), manufactured by Nippon Steel & Sumikin Chemical Co., Ltd.)
Epoxy Resin B: An epoxy resin having an epoxy equivalent weight of 192 g/eq and a melting point of 106° C. (YX-4000 (product name), manufactured by Mitsubishi Chemical Corporation)

[Curing Agent]
A triphenylmethane-type phenol resin having a hydroxyl group equivalent weight of 102 g/eq and a softening point of 70° C. (HE910 (product name), Air Water Inc.)

[Curing Accelerator]
A phosphorus curing accelerator

[Silane Compound]
Silane Compound A: 3-methacryloxypropyltrimethoxysilane (KBM-503 (product name), manufactured by Shin-Etsu Chemical Co., Ltd.)
Silane Compound B: N-phenyl-3-aminopropyltrimethoxysilane (KBM-573 (product name), manufactured by Shin-Etsu Chemical Co., Ltd.)
Silane Compound C: 3-mercaptopropyltrimethoxysilane (KBM-803 (product name), manufactured by Shin-Etsu Chemical Co., Ltd.)

[Inorganic Filler]
Silica Particles: volume average particle diameter: 0.2 μm
Alumina Particles A: volume average particle diameter: 10 μm, cut point: 55 μm
Alumina Particles B: volume average particle diameter; 1 μm, cut point: 25 μm
Magnesium Oxide: volume average particle diameter: approximately 2 μm

[Additives]
Mold release agent: Hoechst wax (HW-E (product name) manufactured by Clariant AG)
Pigment: carbon black (MA-600MJ-S (product name), manufactured by Mitsubishi Chemical Corporation)
Ion exchanger: hydrotalcite (STABIACE HT-P (product name), manufactured by Sakai Chemical Industry Co., Ltd.)

The respective components shown in Table 1 were mixed in the amounts shown in the Table, kneaded, cooled, and pulverized, to prepare an epoxy resin composition. In the Table, the amounts of the components are shown in parts by mass, unless otherwise specified. In the Table, “-” means that the corresponding component is not mixed.

<Evaluation of Viscosity (Evaluation of Spiral Flow)>

Flow distance was evaluated as a length of a molded body obtained by injecting the epoxy resin composition into a spiral flow mold that is compliant with the standard (EMMI-1-66) at an oil pressure of 70 kgf/cm² (approximately 6.86 MPa) in the pressure at the bottom of the plunger, and molding the epoxy resin composition under the condition of 175° C. for 120 seconds.

<Evaluation of Thermal Conductivity>

The epoxy resin composition prepared above was molded using a high-temperature vacuum molding machine under the conditions of 175° C., 120 seconds, and a pressure of 7 MPa, and a test piece was prepared by processing the molded product into a 10 mm square piece having a thickness of 1 mm. The test piece was measured using a HyperFlash Apparatus (product name) manufactured by NETZSCH, at room temperature (25° C.), to obtain the thermal conductivity as a value calculated by the xenon-flush method.

<Evaluation of High Temperature Hardness>

The above-prepared epoxy resin composition was molded using a high-temperature vacuum molding machine under the conditions of 175° C., 120 seconds, and a pressure of 7 MPa, and a value measured using a Shore D Hardness tester was obtained as the hardness.

TABLE 1

| | | | | | Comparative | Comparative | Comparative | Comparative | Comparative |
|---|---|---|---|---|---|---|---|---|---|
| | Item | | Example 1 | Example 2 | Example 1 | Example 2 | Example 3 | Example 4 | Example 5 |
| Composition | Epoxy Resin | Epoxy Resin A | 70.0 | 70.0 | 70.0 | 70.0 | 70.0 | 70.0 | 70.0 |
| | | Epoxy Resin B | 30.0 | 30.0 | 30.0 | 30.0 | 30.0 | 30.0 | 30.0 |
| | Curing Agent | | 55.0 | 55.0 | 55.0 | 55.0 | 55.0 | 55.0 | 55.0 |
| | Curing Accelerator | | 4.0 | 4.0 | 4.0 | 4.0 | 4.0 | 4.0 | 4.0 |
| | Silane | Silane Compound A | 8.75 | 17.5 | — | — | — | — | — |
| | Compound | Silane Compound B | — | — | 8.75 | 17.5 | 17.5 | 17.5 | 17.5 |
| | | Silane Compound C | 0.15 | 0.15 | 0.15 | 0.15 | 0.15 | 0.15 | 0.15 |
| | Mold Release Agent | | 3 | 3 | 3 | 3 | 3 | 3 | 3 |
| | Pigment | | 3.5 | 3.5 | 3.5 | 3.5 | 3.5 | 3.5 | 3.5 |
| | Ion Exchanger | | 5 | 5 | 5 | 5 | 5 | 5 | 5 |
| | Inorganic | Silica Particles | 21 | 22 | 21 | 22 | 19 | 20 | 22 |
| | Filler | Alumina Particles A | 2178 | 2263 | 2178 | 2263 | 2014 | 2132 | 2550 |
| | | Alumina Particles B | 264 | 274 | 264 | 274 | 244 | 258 | 274 |
| | | Magnesium Oxide | 262 | 272 | 262 | 272 | 242 | 257 | — |

| | | | | | | | | |
|---|---|---|---|---|---|---|---|---|
| | Total Amount | 2904.40 | 3019.15 | 2904.40 | 3019.15 | 2707.15 | 2855.15 | 3034.15 |
| | Content of Inorganic Filler in | 79 | 79 | 79 | 79 | 77 | 78 | 79 |
| | Composition (% by volume) | | | | | | | |
| Evaluation | Spiral Flow (inch) | 67.7 | 86.8 | 60.5 | 54.6 | 66.9 | 59.5 | 55.3 |
| | (cm (converted value)) | 172.0 | 220.5 | 153.7 | 138.7 | 169.9 | 151.1 | 140.5 |
| | Thermal Conductivity | 4.95 | 4.87 | 4.62 | 4.90 | 4.63 | 4.74 | 4.90 |
| | (W/(m · K)) | | | | | | | |
| | High Temperature Hardness | 71 | 65 | 75 | 76 | 77 | 79 | 66 |

Results of the evaluations show that, in Examples 1 and 2, in which Silane Compound A was contained, viscosity was lowered and a favorable thermal conductivity of the cured product was obtained. Further, the high temperature hardness was not significantly low as compared to the Comparative Examples, showing that favorable curability was maintained.

The disclosure of Japanese Patent Application No. 2018-049153 is incorporated herein by reference in their entirety. All documents, patent applications, and technical standards mentioned herein are incorporated herein by reference to the same extent as if individual document, patent application, and technical standard were each specifically and individually stated to be incorporated by reference.

1. An epoxy resin composition, comprising:
an epoxy resin;
a curing agent;
alumina particles; and
a silane compound which does not have a functional group that is reactive with an epoxy group and which has a functional group that is unreactive with an epoxy group, wherein the silane compound has a structure in which the functional group that is unreactive with an epoxy resin is bound to a silicon atom, or is bound to a silicon atom via a chain hydrocarbon group having 1 to 5 carbon atoms.

2. The epoxy resin composition according to claim 1, wherein a content of the silane compound is from 0.01% by mass to 20% by mass with respect to a total amount of the epoxy resin.

3. The epoxy resin composition according to claim 1, wherein the functional group that is unreactive with an epoxy resin is at least one selected from the group consisting of a (meth)acryloyl group, a (meth)acryloyloxy group, and a vinyl group.

4. The epoxy resin composition according to claim 1, wherein the silane compound comprises 3-methacryloxypropyltrimethoxysilane.

5. The epoxy resin composition according to claim 1, wherein a content of the alumina particles is 50% by volume or more with respect to a total amount of the epoxy resin composition.

6. The epoxy resin composition according to claim 1, further comprising silica particles.

7. An electronic component device, having an element sealed with the epoxy resin composition according to claim 1.
